(19) United States
(12) Patent Application Publication
(10) Pub. No.: US 2021/0234532 A1
(43) Pub. Date: Jul. 29, 2021

(54) ELECTROACOUSTIC RESONATOR AND RF FILTER COMPRISING AN ELECTROACOUSTIC RESONATOR

(71) Applicant: RF360 EUROPE GMBH, Munchen (DE)

(72) Inventors: Matthias PERNPEINTNER, Munchen (DE); Stefan AMMANN, Großkarolinenfeld (DE); Karl WAGNER, Unterhaching (DE)

(21) Appl. No.: 15/734,526

(22) PCT Filed: Apr. 17, 2019
(86) PCT No.: PCT/EP2019/059980

§ 371 Date: Dec. 2, 2020

(30) Foreign Application Priority Data
Jun. 7, 2018 (DE) 10 2018 113 624.2

(51) Int. Cl. H03H 9/25; H03H 9/02; H03H 9/145; H03H 9/64

(52) U.S. Cl. CPC H03H 9/25; H03H 9/6483; H03H 9/145; H03H 9/02543

(57) ABSTRACT

An electroacoustic resonator (EAR) that allows an RF filter having a large bandwidth is provided. The resonator comprises a piezoelectric material (PM) and an electrode structure (ES, EF) on the piezoelectric material. The piezoelectric material is lithium niobate and has a crystal cut defined by the Euler angles (0°, 80° to 88°, 0°).

The present invention refers to electroacoustic resonators that allow RF filters with a low insertion attenuation and with a relatively large bandwidth. Such filters can be used in mobile communication systems.

RF filters, e.g. in mobile communication systems, are needed to separate wanted RF signals from unwanted RF signals. Bandpass filters should have a low insertion attenuation within a passband and a high insertion attenuation outside the passband. Further, characteristic frequencies of RF filters, e.g. a center frequency of a passband, should be temperature-independent. Further, especially for use in modern RF frequency bands, the obtainable bandwidth of the corresponding RF filter should be large.

Lithium niobate (LiNbO₃) is a known material for electroacoustic resonators. Further, it is known to use a lithium niobate (LN) 128-rot Y-cut wafer to establish electroacoustic resonators for RF bandpass filters.

However, known lithium niobate-based electroacoustic resonators can establish RF filters that require the application of external (i.e. off-chip) coils or inductors to provide a sufficient bandwidth for modern RF applications. Needed external coils or inductors increase the insertion attenuation of the corresponding RF filter due to limited quality factors of the corresponding inductive components. Further, the need for external coils or inductors increases manufacturing costs and spatial dimensions of corresponding filter components.

Thus, it is an object of the present invention to provide an electroacoustic resonator that can be used to establish RF filters that have a good temperature compensation, i.e. a reduced temperature dependence of characteristic frequencies, a large bandwidth, a low insertion attenuation, and that are inexpensive to manufacture. Further, the electroacoustic resonators should be manufacturable using easy-to-handle manufacturing steps. Further, the electroacoustic resonator should render external matching elements, e.g. coils or inductors, for corresponding RF filters redundant.

To that end, an electroacoustic resonator and a corresponding RF filter according to the independent claims are provided. Dependent claims provide preferred embodiments.

The electroacoustic resonator comprises a piezoelectric material and an electrode structure on the piezoelectric material. An acoustic main mode having the acoustic wavelength λ can propagate in the resonator. The piezoelectric material is lithium niobate or doped lithium niobate and has a crystal cut defined by the Euler angles (0°, 80° to 88°, 0°)=(λ′=0°, 80°≤μ≤88°, θ=0°). More preferable are Euler angles (0°, 80° to 83°, 0°).

The electrode structure in combination with the piezoelectric material is used to—due to the piezoelectric effect—convert between RF signals applied to the electrode structure and acoustic waves propagating in a corresponding resonating structure of the resonator.

The acoustic main mode is the desired work mode of the resonator.

The electrode structure can comprise electrode fingers electrically connected to one of two busbars and reflecting elements arranged at distal ends of the corresponding acoustic track to confine acoustic energy in the active area of the resonator.

The orientation of the piezoelectric material's internal crystallographic structure in view of the direction of propagation of the acoustic main mode and the plane in which the electrode structure is arranged on the piezoelectric material is defined by the Euler angles.

In this case, the Euler angles (λ′, μ, θ) are defined as follows: firstly, a set of axes x, y, z are taken as a basis, which are the crystallographic axes of the piezoelectric material.

The first angle λ′ specifies by what magnitude the x-axis and the y-axis are rotated about the z-axis, the x-axis being rotated in the direction of the y-axis. A new set of axes x′, y′, z′ correspondingly arises, wherein z=z′.

In a further rotation, the z′-axis and y′-axis are rotated about the x′-axis by the angle μ. In this case, the y′-axis is rotated in the direction of the z′-axis. A new set of axes x″, y″, z″ correspondingly arises, wherein x′=x″.

In a third rotation, the x″-axis and the y″-axis are rotated about the z″-axis by the angle θ. In this case, the x″-axis is rotated in the direction of the y″-axis. A third set of axes x′″, y′″, z′″ thus arises, wherein z″=z′″.

In this case, the x′″-axis and the y′″-axis are parallel to the surface of the substrate. The z′″-axis is the normal to the surface of the substrate. The x′″-axis specifies the propagation direction of the acoustic waves.

The definition is in accordance with the International Standard IEC 62276, 2005-05, Annex A1.

Thus, a preferred first Euler angle λ′ is 0°. A preferred second Euler angle μ is 80° or larger and 88° or smaller. More preferably the second Euler angle is 83° or less. Further, a preferred third Euler angle θ is 0°. However, tolerances on these numerical values can be in a range of 5° to 10°. Thus, it is possible that the Euler angles are (−5° to 5°, 75° to 93°, −5° to 5°) or (−10° to 10°, 70° to 98°, −10° to 10°).

Such an electroacoustic resonator allows to have a high intrinsic electromechanical coupling coefficient κ² determining the obtainable bandwidth. Thus, an increase in bandwidth can be obtained by using the electroacoustic resonator as described above. This allows to omit external matching elements such as coils or inductors. The result thereof is that corresponding RF filters can be manufactured with smaller spatial dimensions, with reduced manufacturing costs and with less complex manufacturing steps. Further, the insertion attenuation can be reduced resulting in an improved battery life of mobile communication devices.

It is possible that the resonator further comprises a TCF layer (TCF=temperature coefficients of frequencies) arranged on or above the electrode structure and the piezoelectric material.

Characteristic frequencies such as center frequencies of passbands depend on the geometric dimensions of the electrode structure, in particular on the distance between excitation centers defined by the positions of electrode fingers of opposite polarity. Further, the characteristic frequencies also depend on material parameters such as Young's modulus and the velocity of the corresponding acoustic waves. The geometric dimensions and the material parameters are temperature dependent. Changes in temperature, e.g. during operation of the corresponding mobile communication device, would thus lead to a frequency shift of the characteristic frequencies. As a consequence thereof, specifications concerning insertion loss of corresponding frequency bands could not be complied with. Thus, a frequency drift of characteristic frequencies is not wanted. To eliminate, or at least reduce, the detrimental effects of changing temperatures, the TCF layer has temperature-dependent properties such that frequency shifts are compensated. The material of the TCF layer is arranged on the electrode structure where the electrode structure is present on the piezoelectric material. At positions where no electrode structures are arranged on or above the piezoelectric material, the material of the TCF-layer can be arranged directly on the piezoelectric material, e.g. between adjacent electrode fingers.

It is possible that the TCF layer comprises a silicon oxide, e.g. silicon dioxide or an alternative material such as fluorosilicate glass, e.g. SiOF.

It is also possible that the TCF layer consists of one of these materials.

It is possible that the TCF layer has a thickness of 20% to 40% λ. Thus, the thickness of the TCF layer is 20% λ or larger and 40% λ or smaller. In this respect, the thickness of the TCF layer is defined as the distance between the bottom side of the electrode structure and the top surface of the TCF layer. In areas above the electrode fingers the local thickness can be smaller.

It is further possible that the resonator has a passivation layer. The passivation layer is arranged on or above the TCF layer.

If the electroacoustic resonator has a TCF layer, then it is possible that the passivation layer is arranged on the TCF layer. If no TCF layer is present, then the passivation layer can be directly arranged on the electrode structure and the piezoelectric material, respectively,

The passivation layer acts as a barrier for unwanted external influences on the electrode structure, the piezoelectric material and the TCF layer if present. In particular, the passivation layer can prevent water from entering the material of the TCF layer or corrosion of the electrode structure.

It is possible that the TCF layer comprises or consists of silicon oxide (SiO₂) or doped SiO₂.

It is possible that the passivation layer has a thickness of 1% to 4% λ. Thus, the thickness of the passivation layer can be 1% λ or larger and 4% λ or smaller.

It is possible that the passivation layer comprises SiN.

It is possible that the electrode structure comprises a material with a relatively large specific density. In particular, it is possible that the electrode structure comprises a metal selected from gold (Au), copper (Cu), platinum (Pt) and tungsten (W). Further, the electrode structure may be layered including an adhesion layer and/or a barrier layer comprising e.g. Cr or Ti.

The material system comprising the above provided orientation of the piezoelectric material and a “heavy” electrode material provides a waveguide in which acoustic waves can propagate such that good electroacoustic properties of the resonator and of the corresponding RF filter are obtained.

It is possible that the electrode structure has a thickness of 6% to 15% λ. Thus, the electrode structure has a thickness of 6% λ or larger and 15% λ or smaller.

In this respect the thickness of the electrode structure is defined as the distance between the bottom side of the electrode structure directed towards the piezoelectric material and the opposite, top side of the electrode structure.

It is possible that the electrode structure has a layer system comprising one, two, three or more sublayers. Each sublayer can comprise or consist of a different material. However, it is preferred that the main constituent of the electrode structure is a “heavy” metal.

In contrast to conventional electrode structures where the materials of the electrode structures are selected according to their electric properties, in particular according to a high conductivity, the selection of the material of the electrode structure to have a high specific density is new and counterintuitive.

However, despite a possibly increased resistivity of the electrode structure, the overall system of the resonator can provide RF filters with a reduced insertion attenuation due to the above-described reasons.

It is possible that the main mode is a shear mode or a shear-like mode. The main mode is the acoustic mode that essentially contributes to the conversion between RF signals and acoustic waves. Further, it is possible that other modes types e.g. a Rayleigh mode is essentially suppressed. The frequency of the Rayleigh mode resonance to be suppressed may be situated within 2% above the main mode resonance frequency. The frequency of the Rayleigh mode resonance to be suppressed may also be situated within 2% below the main mode resonance frequency.

It is possible that the resonator is a SAW resonator (SAW=surface acoustic wave) or a GBAW resonator (GBAW=guided bulk acoustic wave).

In an SAW resonator the acoustic wave mainly propagates at the top surface of the piezoelectric material.

In a GBAW resonator the acoustic main mode mainly propagates at an interface between the piezoelectric material and a waveguiding layer system arranged above or on the piezoelectric material.

It is possible that the resonator as described above is used to establish an RF filter. Thus, a corresponding RF filter comprises one or more resonators as described above.

The RF filter can comprise its resonators in a ladder-type like circuit topology. In a ladder-type like circuit topology series resonators are electrically connected in series in a signal path between a first port and a second port. Parallel resonators are electrically connected in corresponding parallel shunt paths electrically connecting the signal path to ground.

By utilizing such a ladder-type like topology, bandpass filters or band rejection filters can be established.

Such an RF bandpass filter can be a reception filter or a transmission filter in a mobile communication device, e.g. in a frontend circuit of a mobile communication device. Also, it is possible that the filter is a reception filter or a transmission filter of a duplexer of a mobile communication device or a filter of a multiplexer of a higher degree of a mobile communication device.

It is possible that the filter is a bandpass filter for band 71 or band 28, 71, 41, 42 or 43, or similar applications which require large bandwidths that can be provided by the above-described resonators.

It is possible that the filter is a bandpass filter for band 71 or band 3, 8, 20 or 26.

It is possible that the filter is a bandpass filter for band 71 or band 40, 48, 66 or 68.

With respect to the provided band numbers, it is referred to the standard defining the bands that is valid at the time of filing of the present application.

Characteristic main mode determining parameters have a strong dependence on the cut angle of the piezoelectric material.

Thus, selecting appropriate cut angles is essential for obtaining good electroacoustic properties. With the above-defined Euler angles, cut angles are provided that allow improved electroacoustic properties making improved RF filters with improved electric properties possible.

Central aspects of the present resonator and details of preferred embodiments are shown in the accompanying schematic figures.

In the figures:

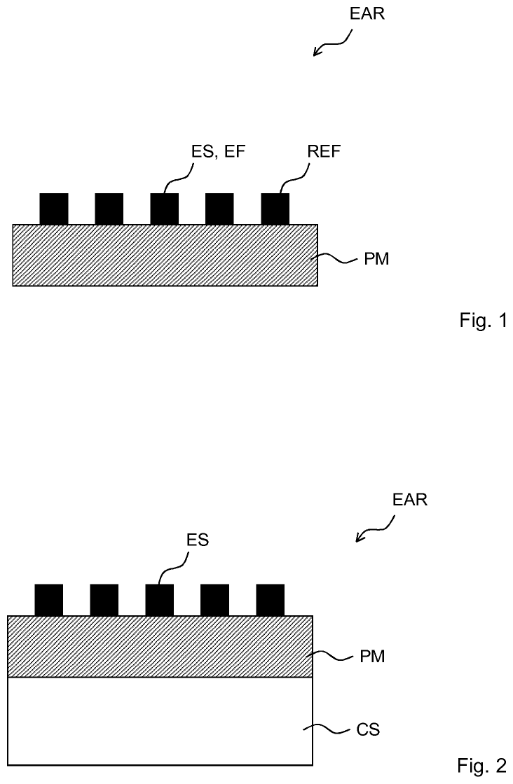

FIG. 1 shows a basic construction of electrode structures on a piezoelectric material;

FIG. 2 shows a piezoelectric material arranged on a carrier substrate;

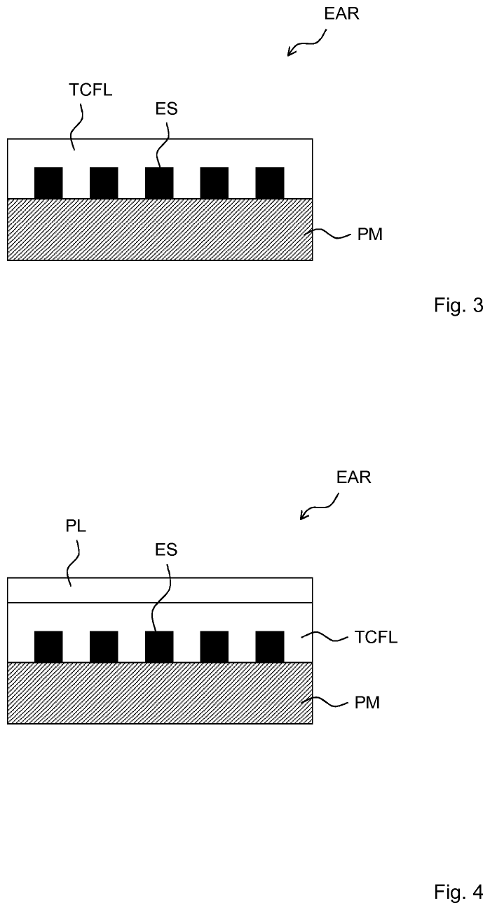

FIG. 3 shows the use of a TCF layer;

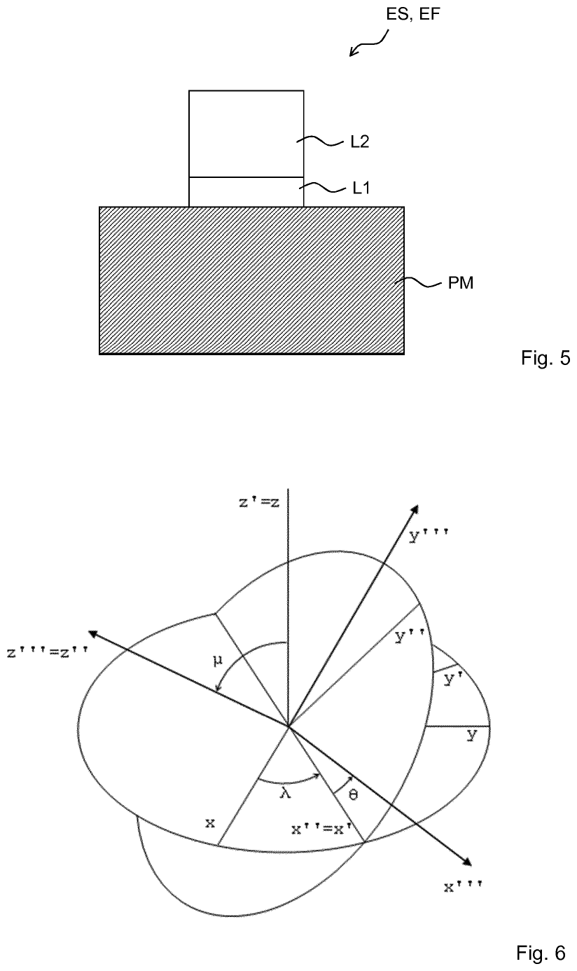

FIG. 4 shows the use of a passivation layer;

FIG. 5 shows an electrode structure comprising different sublayers;

FIG. 6 shows the meaning of the Euler angles λ′, μ, θ; and

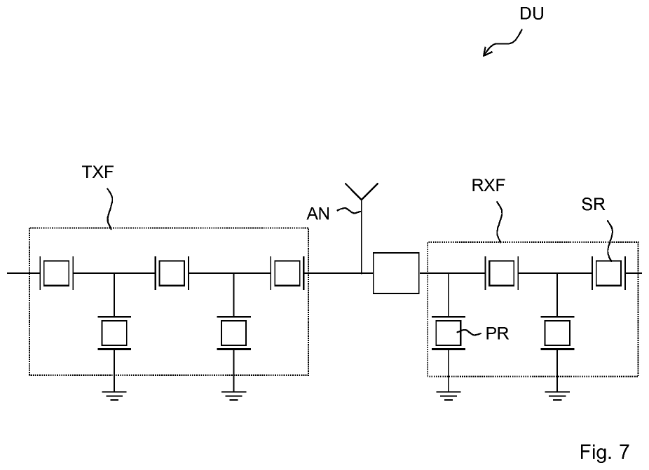

FIG. 7 shows a ladder-type like circuit topology.

FIG. 1 shows a piezoelectric material PM on which an electrode structure ES is arranged. The piezoelectric material PM in combination with the electrode structure ES establish the essential elements of an electroacoustic resonator EAR working with surface acoustic waves. The electrode structure comprises electrode fingers EF arranged on the piezoelectric material PM. The electrode fingers EF extend in a direction orthogonal to the direction of propagation of the main surface acoustic mode. Thus, FIG. 1 shows a cross-section through the corresponding parts of the electroacoustic resonators EAR.

At the distal ends of the acoustic track reflector structures REF, e.g. provided as metallized fingers arranged on the piezoelectric material PM confine acoustic energy to the active area of the resonator.

In FIG. 1 the direction of propagation of the acoustic main mode is in a horizontal direction from left to right. The electrode fingers EF extend in a direction perpendicular to the plane provided by the cross-sectional view of FIG. 1.

It is possible that the piezoelectric material is provided as a monocrystalline material.

FIG. 2 illustrates the possibility of arranging the piezoelectric material PM on a carrier substrate CS.

FIG. 3 shows the possibility of arranging material of a temperature compensation layer TCFL on or above the piezoelectric material PM and the electrode structure ES. The thickness of the TCF layer is defined as the distance between the top side of the electrode structure ES and the top side of the material of the TCF layer TCFL, although also material of the TCF layer TCFL can be arranged between electrode fingers of the electrode structure ES.

FIG. 4 illustrates the possibility of having a passivation layer PL to protect the elements of the resonator arranged below the passivation layer PL. In the layer construction shown in FIG. 4 the passivation layer PL is arranged on the material of the TCF layer TCFL. The material of the TCF layer can comprise a silicon oxide, e.g. silicon dioxide and the passivation layer protects the material of the TCF layer from being contaminated from its environment. In particular, the passivation layer PL protects the material of the TCF layer from coming into contact with water contained in the surrounding air of the atmosphere.

FIG. 5 illustrates the possibility of the electrode structure or of electrode fingers having a layer construction. Thus, the electrode structures and electrode fingers can comprise a sublayer system comprising two or more sublayers. In particular, it is possible that an adhesion layer L1 is arranged between the piezoelectric material PM and other components of the electrode structure ES. The adhesion L1 augments a mechanical connection of the electrode structure to the piezoelectric material.

It is possible that the adhesion layer L1 comprises or consists of titanium.

Other sublayers L2 arranged above the adhesion layer L1 essentially comprise the “heavy” metals for providing the preferred waveguide.

FIG. 6 illustrates the meaning of the Euler angles λ′, μ, θ and their effects on the correspondingly rotated axes.

FIG. 7 illustrates the use of ladder-type like topologies to establish filters, e.g. for a duplexer DU. In a signal path series resonators SR are electrically connected in series between two ports. Parallel resonators PR are arranged in shunt paths between the signal path and ground. With such ladder-type like topologies transmission filters TXF and reception RXF can be provided. A duplexer DU comprises a transmission filter TXF and a reception filter RXF that are connected to a common port at which an antenna AN can be connected.

The electroacoustic resonator and the corresponding RF filter are not limited to the features stated above and the embodiments shown in the figures. A resonator can comprise further elements and layers, e.g. further functional layers or barrier layers, e.g. for establishing an acoustic waveguide. An RF filter can comprise further electroacoustic resonators.

### LIST OF REFERENCE SIGNS

AN: antenna
CS: carrier substrate
EAR: electroacoustic resonator
EF: electrode finger
ES: electrode structure
L1, L2: sublayers of the electrode structure
PL: passivation layer
PM: piezoelectric material
PR: parallel resonator
REF: reflecting structure
RXF: reception filter
SR: series resonator
TCFL: temperature compensation layer, TCF layer
TXF: transmission filter

1. An electroacoustic resonator, comprising
a piezoelectric material and
an electrode structure on the piezoelectric material,
wherein
an acoustic main mode having the wavelength λ can propagate,
the piezoelectric material is lithium niobate or doped lithium niobate and
has a crystal cut defined by the Euler angles (0°, 80° to 88°, 0°).

2. The resonator of claim 1, wherein the piezoelectric material has a crystal cut defined by the Euler angles (0°, 80° to 83°, 0°).

3. The resonator of claim 1, further comprising a TCF layer arranged on or above the electrode structure and the piezoelectric material.

4. The resonator of claim 3, wherein the TCF layer comprises SiO₂ or SiOF.

5. The resonator of claim 3, wherein the TCF layer has a thickness of 20% to 40% λ.

6. The resonator of claim 1, further comprising a passivation layer arranged on or above the TCF layer.

7. The resonator of claim 6, wherein the passivation layer comprises SiN.

8. The resonator of claim 6, wherein the passivation layer has a thickness of 1% to 4% λ.

9. The resonator of claim 1, wherein the electrode structure comprises a metal selected from Au, Cu, Pt and W.

10. The resonator of claim 1, wherein the electrode structure has a thickness of 6% to 15% λ.

11. The resonator of claim 1, wherein the main mode is a shear mode or a shear-like mode.

12. The resonator of claim 1, being a SAW resonator or a GBAW resonator.

13. An RF filter comprising a resonator of claim 1.

14. The RF filter of claim 13, being a band pass filter for band 28, 71, 41, 42 or 43.

15. The RF filter of claim 13, being a band pass filter for band 3, 8, 20 or 26.

16. The RF filter of claim 13, being a band pass filter for band 40, 48, 66 or 68.
